(19) United States
(12) Patent Application Publication
(10) Pub. No.: US 2008/0206960 A1
(43) Pub. Date: Aug. 28, 2008

(54) REWORKABLE CHIP STACK

(75) Inventors: Bing Dang, Chappaqua, NY (US); Mario J. Interrante, New Paltz, NY (US); John Knickerbocker, Monroe, NY (US); Edmund J. Sprogis, Underhill, VT (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/679,226

(22) Filed: Feb. 27, 2007

(51) Int. Cl. H01L 21/30

(52) U.S. Cl. 438/459; 257/E21.085

(57) ABSTRACT

A method for removing a thinned silicon structure from a substrate, the method includes selecting the silicon structure with soldered connections for removal; applying a silicon structure removal device to the silicon structure and the substrate, wherein the silicon structure removal device comprises a pre-determined temperature setpoint for actuation within a range from about eighty percent of a melting point of the soldered connections to about the melting point; heating the silicon structure removal device and the soldered connections of the silicon structure to within the range to actuate the silicon structure removal device; and removing the thinned silicon structure. Also disclosed is a structure including a plurality of layers, at least one layer including a thinned silicon structure and solder coupling the layer to another layer of the plurality; wherein the solder for each layer has a predetermined melting point.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to assembling and disassembling semiconductor devices in a stack arrangement.

2. Description of the Related Art

Miniaturized devices may be manufactured into the surface of a semiconductor substrate. The miniaturized devices may include electronic circuits referred to as integrated circuits and optical devices. The optical devices may include an array of micro-lenses, photo-detectors, and vertical cavity surface emitting lasers (VCSEL). The miniaturized devices are referred to as “silicon structures.” Multiple silicon structures also referred to as “chips” may be placed on a semiconductor substrate and interconnected with other silicon structures. Thinned silicon structures may be stacked vertically and interconnected with wire bonds or through-silicon-vias (TSV) in order to save space. In each case, the chips or stacks of silicon structures are typically mounted on a silicon package or semiconductor substrate that provides for at least one of electrical and optical interconnections to a board within a product or system.

As the technology to manufacture the silicon structures improves, thinner silicon structures, referred to as “thinned silicon structures,” are possible. The thinned silicon structures may be manufactured with micro-scale and even nano-scale dimensions. Smaller thicknesses provide for increasing densities of stacked silicon structures. The thinned silicon structures with integrated feature sizes in micron and nano dimensions can be sensitive to stresses in addition to the stacked silicon structures themselves having need for consideration of mechanical, thermal, processing, handling and system imposed stresses. As one can imagine, with decreasing dimensions with advances in each silicon generation and the increasing densities from stacking the thinned silicon structures, more opportunities for failures of the silicon structures and the stacks of silicon structures may be possible.

The failure of just one silicon structure in the stack of silicon structures may render the entire stack inoperable. The smaller thicknesses also make the silicon structures more fragile and difficult to work with. Silicon interposers may be used between the thinned silicon structures and the semiconductor substrate to provide mechanical support or to reduce stress. The silicon interposers may also provide for wiring, passive circuits such as those using an integrated decoupling capacitor, or active circuits such as those for voltage regulation and clocking. Typically, the silicon interposers are fabricated from at least one of ceramic, organic, and silicon materials.

Processes have been developed which can remove standard chips from a multichip module to permit replacement with a good chip or to reuse the chip when the semiconductor substrate has defects. The repair typically includes removing and replacing at least one failed silicon chip or silicon package. Room temperature shear and other techniques normally used for standard 730 micron thickness silicon chips have been attempted as a way to remove the thinned silicon structures, thinned silicon packages and thinned silicon interposers. In many cases, the thinned silicon structures and the thinned silicon packages failed due to cracking or damage during removal. When these techniques are used to disassemble the thinned silicon structures, often the thinned silicon structures are cracked or damaged, an associated silicon structure is cracked or damaged, or remaining silicon structures in the stack of silicon structures are damaged so as to render hardware (such as silicon structures, silicon packages, silicon interposers, and stacks of silicon structures) unfit for reuse.

One technique uses a gripper device also referred to as a “spider” to pull the silicon structure out of the substrate while soldered connections are heated. Vertical force is applied with a bimetallic spring. Typically, the solder is heated well below a melting point. The gripper attaches to the edges or under the silicon structure. With the thinned silicon structures, the force necessary to pull the silicon structure out of the semiconductor substrate can crack or damage the silicon structures. This is undesirable if there is interest to save the thinned silicon structure or the thinned silicon package.

Another technique for removing the silicon structure from a semiconductor substrate uses a horizontal shear force. In one example, a tool applies the horizontal shear force to the edge of the chip and thus shears the soldered connections at room temperature. An amount of horizontal shear force must be high enough to remove the silicon structure, which may contain hundreds or thousands of connections. Often the amount of horizontal shear force needed to remove the thinned silicon structure causes damage to the thinned silicon structure. The damage is such that the thinned silicon structure cannot be removed with this process.

The problems as described above have also occurred with attempts to remove the thinned silicon interposer and the thinned silicon package.

The techniques described above have also been used to attempt to remove the thinned silicon structures and the thinned silicon interposers within the stack of thinner silicon structures. Typically, the attempts result in damaged silicon structures and silicon interposers that cannot be removed and reused.

During a manufacturing process for the stack of silicon structures, it is sometimes advantageous to solder the silicon structures to a “temporary chip attachment”(TCA) device for testing purposes. Typically, the TCA device is fabricated from a semiconductor substrate. The silicon structure is removed from the TCA device for incorporation into the stack of silicon structures. Removal from the TCA device may be difficult with the thinner silicon structures.

What are needed are methods and structures to remove the thinned silicon structures and the thinned silicon interposers from at least one of the semiconductor substrate and the stack of thinned silicon structures.

### SUMMARY OF THE INVENTION

The shortcomings of the prior art are overcome and additional advantages are provided through a method for removing a thinned silicon structure from a substrate, the method includes selecting the thinned silicon structure with soldered connections for removal; applying a silicon structure removal device to the silicon structure and the substrate, wherein the silicon structure removal device comprises a pre-determined temperature setpoint for actuation within a range from about eighty percent of a melting point of the soldered connections to about the melting point; heating the silicon structure removal device and the soldered connections of the silicon structure to within the range to actuate the silicon structure removal device; and removing the thinned silicon structure.

Also disclosed is a structure including a plurality of layers, at least one layer including a thinned silicon structure and solder coupling the layer to another layer of the plurality; wherein the solder for each layer has a predetermined melting point.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution with a method for removing a thinned silicon structure from a substrate, the method includes selecting the silicon structure with soldered connections for removal; applying a silicon structure removal device to the silicon structure and the substrate, wherein the silicon structure removal device comprises a predetermined temperature setpoint for actuation within a range from about eighty percent of a melting point of the soldered connections to about the melting point; heating the silicon structure removal device and the soldered connections of the silicon structure to within the range to actuate the silicon structure removal device; and removing the thinned silicon structure.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1A, 1B, 1C, and 1D (collectively referred to as FIG. 1) depict aspects of an exemplary example of removing and replacing an assembly of a silicon structure and a silicon interposer;

FIGS. 2A, 2B, 2C, and 2D (collectively referred to as FIG. 2) depict aspects of an exemplary example of removing and replacing a stack of silicon structures with a solder temperature hierarchy;

FIG. 3 presents an exemplary method for removing at least one silicon structure from at least one of a substrate and other silicon structures; and

FIG. 4 presents an exemplary method for fabricating the stack of silicon structures with the solder hierarchy to provide for removing at least one of the silicon structures.

The detailed description explains the preferred embodiments of the invention, together with advantages and features, by way of example with reference to the drawings.

### DETAILED DESCRIPTION OF THE INVENTION

The teachings herein provide for methods and structures for removing silicon structures and silicon interposers from at least one of substrates and stacks of silicon structures where the stacks may include silicon interposers. The teachings herein related to the silicon structures also apply to the silicon interposers. Typically, soldered connections hold the silicon structures in place. The methods call for using a silicon structure removal device. The silicon structure removal device may be at least one of a gripper device and a horizontal shear device. The silicon structure removal device may be used to remove at least one of the silicon structures and the silicon interposers. The silicon structure removal device is applied to a silicon structure intended for removal. The silicon structure removal device and the silicon structure are placed in an oven. The oven heats the soldered connections to temperatures higher than temperatures used in the past for thicker silicon structures. When the silicon structure removal device reaches a pre-determined temperature, the silicon structure removal device automatically actuates to remove the silicon structure and may be aided by gravity or a vertical component in addition to a horizontal shear force.

The teachings also provide a method to fabricate the stacks of silicon structures to provide for removing the silicon structures with less risk of damage to the silicon structures being removed and those silicon structures remaining. The method calls for using solders with different melting points and connections that survive higher temperatures. A solder with a lower melting point is used to connect the silicon structure that may be anticipated to require future removal. The solder has a lower melting point than other solders used in the stack of silicon structures. Because of the lower melting point, the silicon structure may be removed without disturbing other silicon structures in the stack of silicon structures. Similarly, a hierarchy of solders with different melting points may be used for connections of the silicon structures in a stack. The silicon structure with the lowest melting point solder may be removed first. The silicon structure with the next lowest melting point may be removed second and so forth. The silicon structures anticipated not to require future removal may be connected with the connections that survive higher temperatures. Before the methods and alignment features are described in detail certain definitions are provided.

A “stack of silicon structures” relates to two or more silicon structures bonded together in a vertical structure. The silicon structures may include silicon interposers. A “gripper device” (also known as a “spider device”) relates to a device to remove the silicon structures and the silicon interposers. Typically, the gripper device includes a bimetallic spring. In general, the gripper device is applied to the silicon structure intended for removal. The gripper device, the silicon structure and associated soldered connections are heated in an oven. The heating lessens an amount of force necessary to remove the soldered connections. At a pre-determined temperature, the bimetallic spring applies force to remove the silicon structure. The gripper device used herein does not grip edges of the silicon structure. Gripping the edges may cause damage to thin silicon structures and other associated thinned silicon structures preventing removal of some or all of the thinned silicon structures. The teachings herein call for using at least one of a suction device when contacting the back of the silicon structure and an organic cushion, a metal coated rubber cushion and a metal coated polymer cushion for attaching the gripping device to an edge of the thinned silicon structure during the application of the horizontal shear force to the edge of the thinned silicon structure. The suction device, the organic cushion, and the metal coated rubber or polymer act to distribute the force removing the silicon structure. A “horizontal shear device” relates to a device for providing a horizontal shear force to a silicon structure intended for removal. Typically, the horizontal shear device is applied to the silicon structure intended for removal. The silicon structure and the horizontal shear device are placed in an oven. The oven heats the soldered connections. At a pre-determined temperature, a horizontal shear force is automatically applied to the silicon structure. The horizontal shear force causes the silicon structure to be removed. A “substrate” relates to a semiconductor to which at least one of the silicon structure and the silicon interposer are connected. The substrate may be a silicon package containing miniaturized devices such as electronic circuits and optical devices.

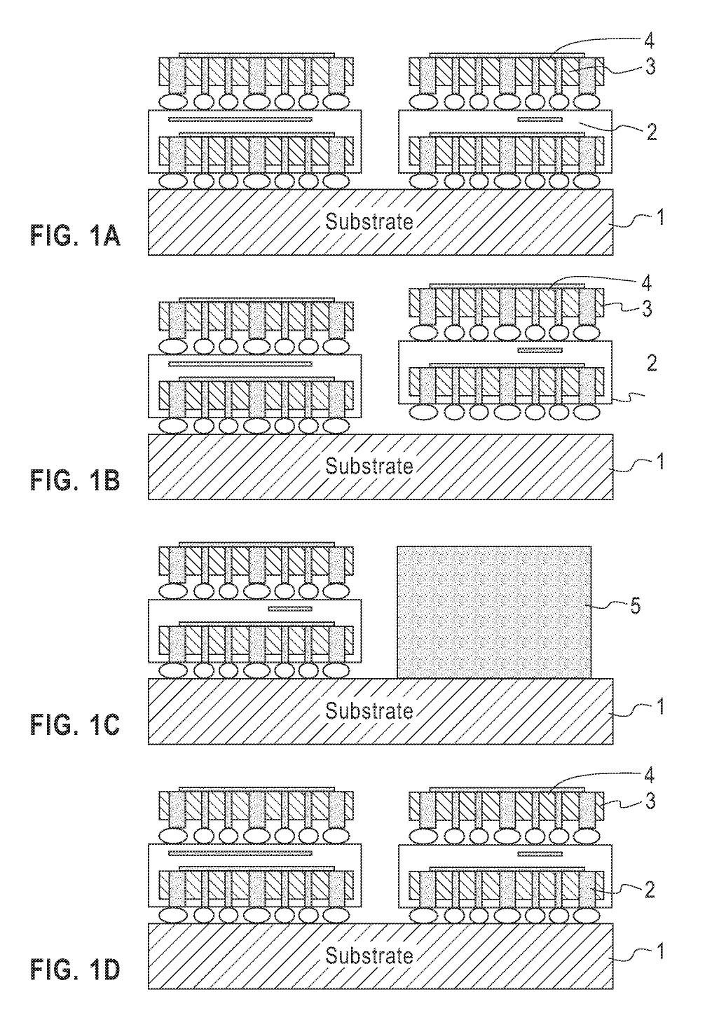

FIG. 1 depicts aspects of an exemplary example of removing and replacing an assembly of a silicon structure 3 and a silicon interposer 2. Referring to FIG. 1A, the silicon structure 3 is connected to the silicon interposer 2. In this example, the silicon structure 3 and the silicon interposer 2 are removed together as a stack of silicon structures 4. All soldered connections in this example use solder with the same melting point. Referring to FIG. 1B, the silicon structure removal device is applied to the stack of silicon structures 4 and a substrate 1. The silicon structure removal device and soldered connections between the silicon interposer 2 and the substrate 1 and are heated. Typically, the silicon structure removal device and the soldered connections are heated to a pre-determined temperature suitable for the silicon structure removal device to remove the silicon interposer 2 from the substrate 1. The silicon structure removal device is automatically actuated at about the pre-determined temperature removing the stack of silicon structures 4 from the substrate 1. Referring to FIG. 1C, a porous copper block 5 is heated and applied to a remainder of solder on the substrate 1. The porous copper block 5 removes the remainder of solder. Referring to FIG. 1D, the stack of silicon structures 4 with the silicon structure 3 that operates correctly is soldered to the substrate 1.

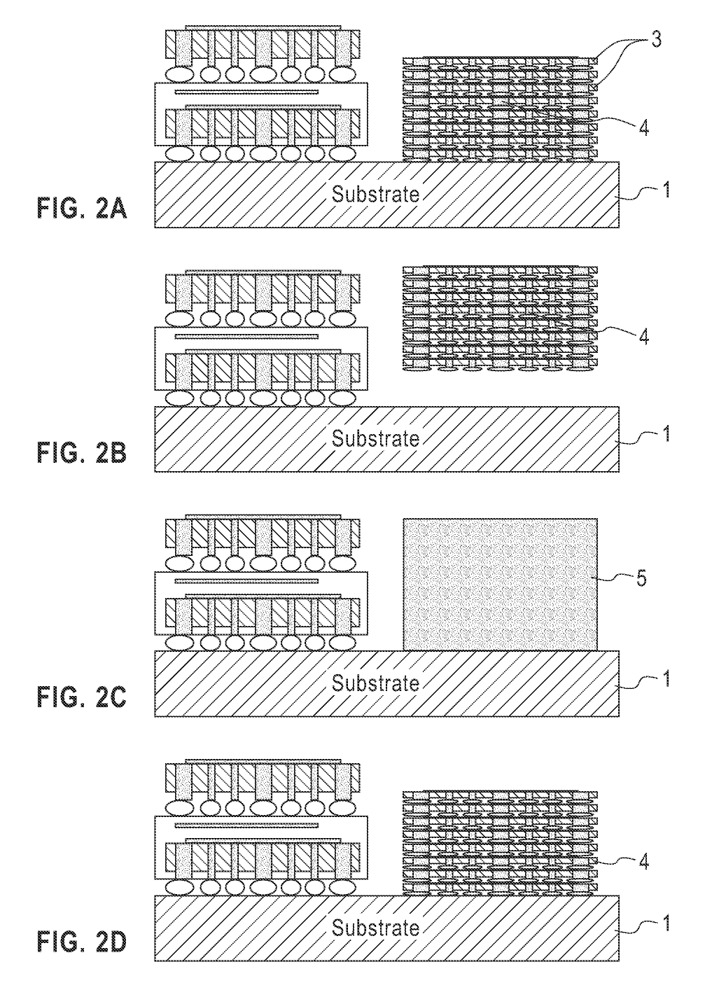

FIG. 2 depicts aspects of an exemplary example of repairing the stack of silicon structures 4 connected to the substrate 1. Referring to FIG. 2A, the stack of silicon structures 4 includes a plurality of the silicon structures 3. Any of the silicon structures 3 may represent the silicon interposer 2. In this example, the stack of silicon structures 4 includes at least one failed silicon structure 3. Repairing the stack of silicon structures 4 includes removing the stack of silicon structures 4 from the substrate 1. The repairing also includes installing the stack of silicon structures 4 in which all of the silicon structures 3 operate correctly. In anticipation of this type of repairing, connections between the silicon structure 3 and the substrate 1 use a solder with a melting point lower (i.e., for example 37/63 lead-tin solder with about 183° C. melting point) than the melting points of the solders (i.e., for example 97/3 lead-tin solder with about 320° C. melting point) used to make the other connections in the stack of silicon structures 4. Referring to FIG. 2B, the silicon structure removal device is applied to the stack of silicon structures 4. The stack of silicon structures 4, the silicon structure removal device and the substrate 1 are heated to a pre-determined temperature related to the melting point for the solder used in the connections between the silicon structure 3 and the substrate 1. At about the pre-determined temperature, the silicon structure removal device is automatically actuated to remove the stack of silicon structures 4. Referring to FIG. 2C, the porous copper block 5 is heated and used to remove excess solder from a location on the substrate 1 where the stack of silicon structures 4 was removed. Referring to FIG. 2D, a further step in the repairing includes connecting the stack of silicon structures 4 with the silicon structures 3 that all operate correctly to the substrate 1. In anticipation of a future repair to the stack of silicon structures 4, the solder used in the connections between the silicon structure 3 and the substrate 1 has a lower melting point than the other solders used in the stack of silicon structures 4.

Referring to FIG. 2A, the silicon structures 3 in the stack of silicon structures 4 may use connections related to a hierarchy of temperatures. The silicon structures 3 may be selectively removed based upon a temperature related to connections to other silicon structures 3. For example, a connection related to a solder with a lowest melting point may be removed first. A connection related to a solder with a second lowest melting point may be removed second and so forth. Besides the lead-tin solders discussed above, exemplary embodiments of solders with the hierarchy of temperatures include gold-tin solder (80% Au, 20% Sn) with an approximately 280° C. melting point, and tin-copper-silver family of lead-free solders (with the tin greater than 95%) with melting points of approximately 217° C. to 231° C. Other solder compositions with various solder temperature hierarchies may also be used such as Au—In or in combination with solders which form intermetallic compounds such as SnCu or SnCuNi and thus alter their “effective melting point” after some temperature and time of reactions.

In certain situations, it may be advantageous to have connections with the silicon structures 3 and the silicon interposers 2 that are considered permanent-type connections. Typically, connections are considered the permanent-types connections, if the connections can withstand a temperature of approximately 400° C. In general, silicon substrates and wafers can withstand temperatures up to approximately 400° C. Therefore, the silicon substrates and wafers may be damaged in any attempts to remove connections that involve heating to temperatures greater than approximately 400° C. Exemplary embodiments of the permanent-type connections include copper studs, copper-to-copper bonding, and transient liquid phase solders. For copper-to-copper bonding, one embodiment includes a temperature of approximately 350° C., applied force of approximately 60-400 psi, and an ambient environment of reduced oxygen. The ambient environment of reduced oxygen may include an inert atmosphere such as nitrogen, reducing atmosphere forming gas (% nitrogen plus % hydrogen), or a combination of formic acid vapor and nitrogen. The transient liquid phase solders have a property of having a lower melting point a first time the transient liquid phase solder is melted. A second time the transient liquid phase solder is melted requires a higher melting point. For example, a tin-copper liquid phase solder has an initial melting point of approximately 227° C. but requires a temperature greater than 400° C. to melt the reacted intermetallic compounds, if completely reacted, a second time.

High temperature underfills may be used to surround connections that are intended to be of the permanent type. For example, the high temperature underfills may withstand temperatures of 350° C. to over 400° C. The high temperature underfills such as but not limited to polyimide based materials or derivatives may bond together the silicon structures 3 to other silicon structures 3. The high temperature underfills keep connections intact in environments of 350° C. to over 400° C. for some period of time, which is typically longer at lower elevated temperatures of about 200-300° C., shorter periods of time for about 300-350° C. and much shorter periods of time for about 350-400° C.

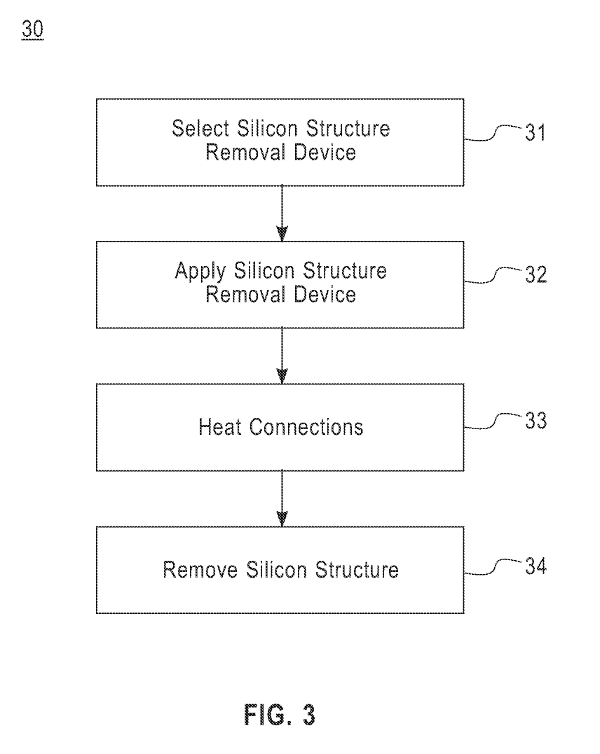

FIG. 3 presents an exemplary method 30 for removing at least one silicon structure 3 from at least one of the substrate 1 and other silicon structures 3. Any of the silicon structures 3 may represent the silicon interposers 2. A first step 31 calls for selecting the silicon structure removal device. The silicon structure removal device may be at least one of the gripper device and the horizontal shear device among others. When the gripper device is selected, at least one of the suction device, the organic cushion, the metallic coated polymer cushion and the metallic coated rubber cushion discussed above will be used in conjunction with the gripper device. A second step 32 calls for applying the silicon structure removal device. A third step 33 calls for heating the silicon structure removal tool and the connections intended for removal to a pre-determined temperature. Typically, the pre-determined temperature is selected to be in a range of from eighty percent of the melting point of the solder to the melting point. In general, the pre-determined temperature for use with the horizontal shear device does not include the melting point. The pre-determined temperature for use with the gripper device may include the melting point. A fourth step 34 calls for removing the silicon structure 3. In general, the silicon structure removal device will automatically actuate at about the pre-determined temperature.

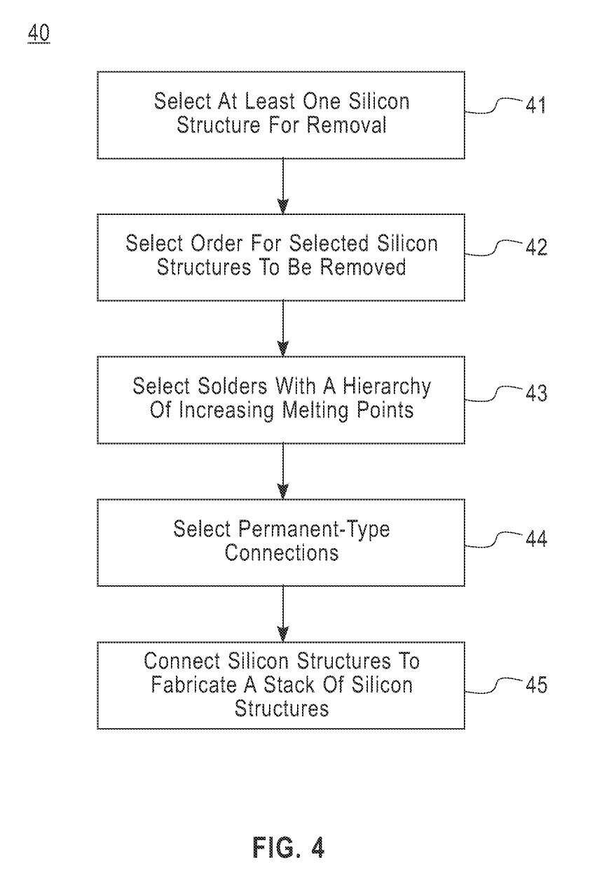

FIG. 4 presents an exemplary method 40 for fabricating a stack of silicon structures 4 to provide for removing at least one of the silicon structures 3. Any of the silicon structures 3 may represent the silicon interposers 2. A first step 41 calls for selecting at least one silicon structure 3 for removal. A second step 42 includes selecting an order for removal of the selected silicon structures 3. A third step 43 includes selecting solders for use in connecting the selected silicon structures 3. The selected solders have a hierarchy of increasing melting points. The solder with the lowest melting point is designated for the silicon structure 3 selected to be removed first. The solder with the second lowest melting point is designated for the silicon structure 3 selected to be removed second and so forth. A fourth step 44 includes selecting the permanent-type connections for the silicon structures 3 not selected for removal. A fifth step 45 calls for connecting the silicon structures 3 using the solders and the permanent-type connections selected to fabricate the stack of silicon structures 4. In general, the silicon structures 3 are connected with solders and connections that have a pre-determined melting point.

Certain considerations may arise when removing the silicon structure 3. The considerations include sizes of bonding areas in the soldered connections and surface tensions of the solders. The considerations may require at least one of increasing the amount of force applied by the silicon structure removal device and increasing the pre-determined temperature closer to the melting point of the solder. Increasing the amount of force may cause damage to thinner silicon structures 3. Therefore, it may be more appropriate to increase the pre-determined temperature closer to the melting point.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for removing a thinned silicon structure from a substrate, the method comprising:
selecting a thinned silicon structure with soldered connections for removal;
applying a silicon structure removal device to the thinned silicon structure and the substrate, wherein the silicon structure removal device comprises a pre-determined temperature setpoint for actuation within a range from about eighty percent of a melting point of the soldered connections to about the melting point;
heating the silicon structure removal device and the soldered connections of the thinned silicon structure to within the range to actuate the silicon structure removal device; and
removing the thinned silicon structure.

2. The method as in claim 1, wherein selecting comprises selecting at least one silicon interposer with soldered connections.

3. The method as in claim 1, wherein applying comprises applying at least one of a gripper device and a horizontal shear device.

4. The method as in claim 3, wherein applying at least one of a gripper device comprises applying a gripper device with at least one of a suction device adapted for attaching to a back the thinned silicon structure, an organic cushion, a metallic coated polymer cushion, and a metallic coated rubber cushion adapted for attaching to an edge of the thinned silicon structure.

5. A structure comprising a plurality of layers, at least one layer comprising a thinned silicon structure and solder coupling the layer to another layer of the plurality; wherein the solder for each layer has a predetermined melting point.

6. The structure of claim 5, further comprising at least one of lead-tin solders, gold-tin solders, gold-indium solders, tin-copper-nickel, tin-copper-indium, tin-copper-silver solders, transient liquid phase solders, high temperature underfills, copper studs, and copper-to-copper bonding.
